(19) United States
(12) Patent Application Publication
(10) Pub. No.: US 2021/0029459 A1
(43) Pub. Date: Jan. 28, 2021

(54) Sounding Device and Mobile Terminal

(71) Applicant: AAC Technologies Pte. Ltd., Singapore city (SG)

(72) Inventors: Xingzhi Huang, Shenzhen (CN); Lin Liu, Shenzhen (CN); Dijiang Tong, Shenzhen (CN); Zhe Zhang, Shenzhen (CN); Jun Wu, Shenzhen (CN); Zhichen Chen, Shenzhen (CN); Zhaoyu Yin, Shenzhen (CN)

(21) Appl. No.: 16/995,772

(22) Filed: Aug. 17, 2020

Related U.S. Application Data
(63) Continuation of application No. PCT/CN2019/098140, filed on Jul. 29, 2019.

(30) Foreign Application Priority Data
Jul. 22, 2019 (CN) 201921159396.9

(51) Int. Cl. H04R 9/02; H04R 1/02; H04R 1/28; H05K 7/20

(52) U.S. Cl. CPC H04R 9/022; H04R 1/025; H04R 2201/02; H05K 7/20263; H04R 1/2811

(57) ABSTRACT

A sounding device includes a speaker box, and a thermally conductive member. The speaker box has a first housing body with a first accommodation space and a speaker unit accommodated in the first housing body. The speaker unit includes a diaphragm dividing first accommodation space into a front acoustic cavity between the diaphragm and the first housing body. The thermally conductive member includes a first part, a second part connected with the heat source component. The heat generated by the heat source component is conducted to the air in the sound channel through the thermally conductive member. By virtue of an air cooling effect of the speaker unit, the heat of the thermally conductive member is rapidly conduced into outer air, and thus the heat radiation efficiency can be remarkably improved.

### FIELD OF THE PRESENT DISCLOSURE

The present application relates to technical field of communication devices, and in particular relates to a sounding device and a mobile terminal with heat dissipating function.

### DESCRIPTION OF RELATED ART

With the advent of the mobile Internet era, the number of smart mobile terminals is increasing continuously. Among many mobile devices, mobile phone is undoubtedly the most common and portable mobile terminal. At present, a mobile phone has a diversity of functions, one is a high-quality music function, and therefore, a sounding device for broadcasting sound is massively applied to current intelligent mobile terminals.

In the related art, a mobile terminal has small internal space, and a great number of heat source components, such as CPUs and batteries, are integrated in the mobile terminal, therefore, a great deal of heat can be generated after long-term operation of the mobile terminal, and the problem of heat radiation becomes a main technical difficulty which restricts development of mobile terminals.

### SUMMARY OF THE INVENTION

One of the main objects of the present invention is to provide a sounding device with heat dissipation function. Another object of the invention is to provide a mobile terminal having such a sounding device.

Accordingly, the present invention provides a sounding device, comprising:

a speaker box for generating sound, comprising a first housing body with a first accommodation space, and a speaker unit accommodated in the first housing body and comprising a diaphragm for generating sounding;

a heat source component spaced from the speaker box;

a thermally conductive member connected with the speaker box and the heat source component; wherein

the diaphragm partitions the first accommodation space into a front acoustic cavity between the diaphragm and the first housing body;

the first housing body comprises a sound channel communicating the front acoustic cavity with the outside and a through opening penetrating through the first housing body;

the thermally conductive member comprises a first part which is embedded into the first housing body and completely covers the through opening, a second part connected with the heat source component, and a connection part connected with the first part and the second part;

the first part and the first housing body encircles the sound channel together; the first part is arranged at one end of the sound channel close to the front acoustic cavity; and heat generated by the heat source component is conducted into the air in the sound channel through the thermally conductive member.

In addition, the first part comprises a metal heat radiation sheet in integral injection molding with the first housing body and the thermally conductive element adhered to an outer surface of the metal heat radiation sheet.

In addition, the metal heat radiation sheet is a steel piece or a copper piece.

In addition, the thermally conductive member is a liquid cooling type thermally conductive vessel.

In addition, the thermally conductive member is a solid heat conduction metal piece.

In addition, an inner surface of the first part right aligned to the sound channel is flush with an inner surface of the first housing body on a circumferential side.

In addition, the first part, the second part and the connection part are integrally arranged.

In addition, a cross section area of the connecting part of the first part and the connection part along a thickness direction is greater than a cross section area of the connecting part of the connection part and the first part along the thickness direction.

In addition, the first housing body comprises a lower housing body and an upper housing body which is assembled with the lower housing body to form the first accommodation space; the upper housing body comprises a top wall and a side wall which extends to the lower housing body from the top wall; the sound channel is arranged at the upper housing body; and the first part is embedded into the top wall.

The present invention further provides a mobile terminal, comprising a sounding device as described above, a second housing with a second accommodation space, and a voice outlet formed in the second housing, wherein the sounding device is accommodated in the second housing, and the sound channel communicates with the voice outlet.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is an isometric view of a sounding device in accordance with an exemplary embodiment of the present application;

FIG. 2 is an exploded view of the sounding device;

FIG. 3 is a cross-sectional view of the sounding device of a first embodiment of the present application taken along line A-A in FIG. 1;

FIG. 4 is a cross-sectional view of a sounding device of a second embodiment of the present application;

FIG. 5 is an illustration of a mobile terminal of the present application.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby are only to explain the disclosure, not intended to limit the disclosure.

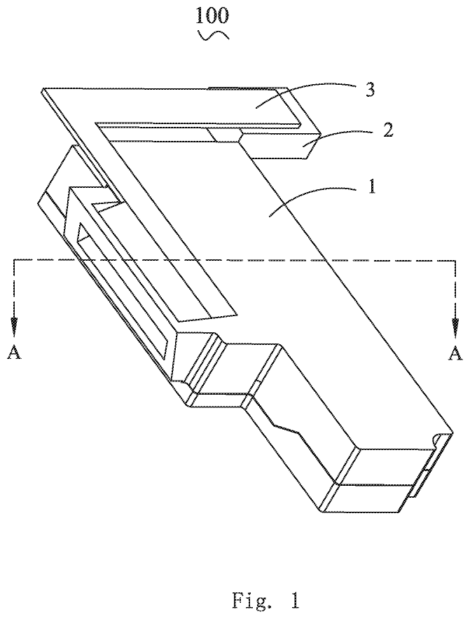

Referring to FIG. 1, the present application provides a sounding device 100 which comprises a speaker box 1, a heat source component 2 which is arranged at an interval with the speaker box 1, and a thermally conductive member 3 connected with the speaker box 1 and the heat source component. One end of the heat source component 2 is connected with the speaker box 1, and the other end is connected with the thermally conductive member 3. Air is pushed to flow through vibration generated when the speaker box 1 works, and furthermore, heat radiation of the thermally conductive member 3 is accelerated through the flowing air.

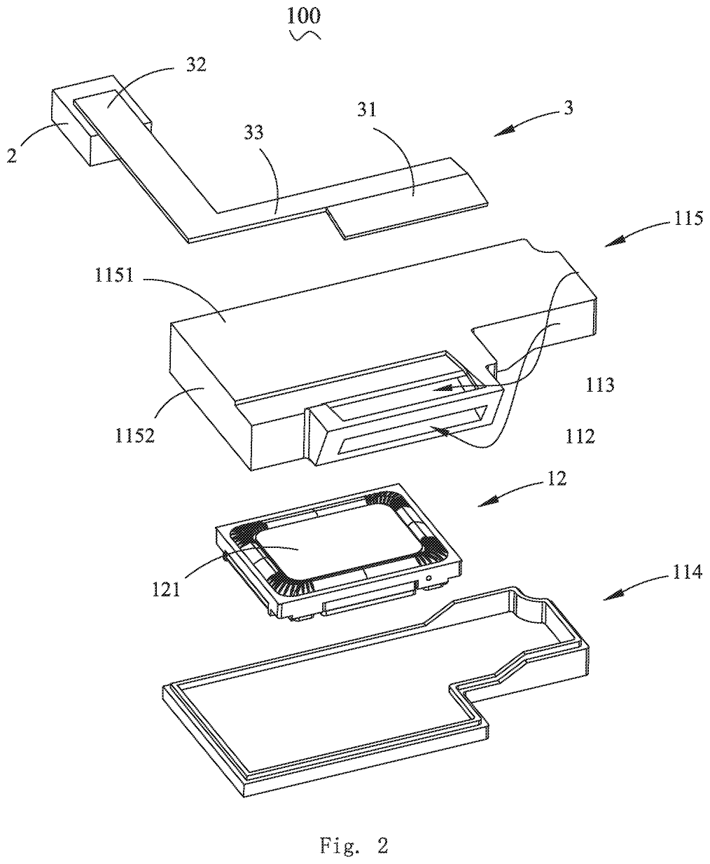

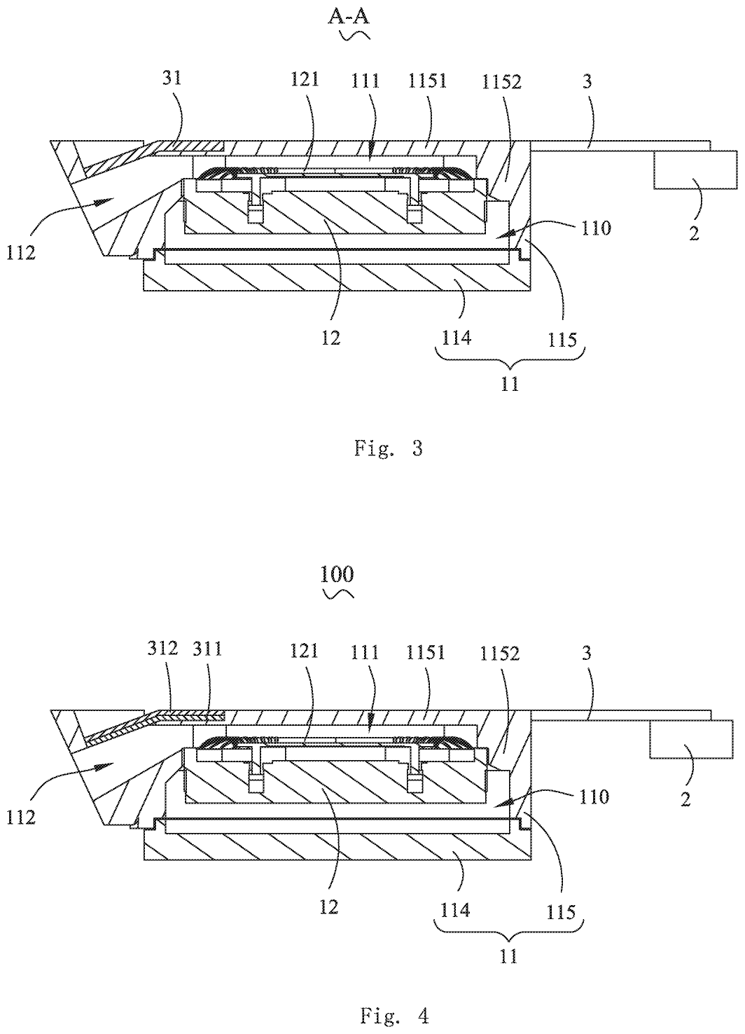

As shown in FIGS. 2-3, the speaker box 1 comprises a first housing body 11 with a first accommodation space 110 and a speaker unit 12 accommodated in the first housing body 11. The speaker unit 12 comprises a diaphragm 121 for vibration sounding. The diaphragm 121 partitions the first accommodation space 110 into a front acoustic cavity 111 between the diaphragm 121 and the first housing body 11. The first housing body 11 comprises a sound channel 112 communicating the front acoustic cavity 111 with the outside and a through opening 113 penetrating through the first housing body 11.

The thermally conductive member 3 comprises a first part 31 which is embedded into the first housing body 11 and completely covers the through opening 113, a second part 32 connected with the heat source component 2 and a connection part 33 for connecting the first part 31 with the second part 32. The first part 31 and the first housing body 11 encircle the sound channel 112 together. The first part 31 is arranged at one end of the sound channel 112 close to the front acoustic cavity 111. And heat radiation by the heat source component 2 is conducted to air in the sound channel 112 through the thermally conductive member 3.

Specifically, when the diaphragm 121 vibrates up and down and the volume of the front acoustic cavity 111 is reduced, at the moment, the air in the front acoustic cavity 111 is extruded outside through the sound channel 112 and the heat is conducted outside. And when the diaphragm 121 vibrates up and down again, the volume of the front acoustic cavity 111 is increased, outer air is sucked into the front acoustic cavity 111, therefore, through up and down vibration of the diaphragm 121, air convection is achieved, and the heat of the heat source component 2 is continuously conducted outside, and a purpose of heat radiation is achieved.

The inner surface of the first part 31 right aligned to the sound channel 112 is arranged flush with the inner surface of the first housing body 11 on a circumferential side, thereby ensuring that the inner wall of the sound channel 112 is smooth, and no air turbulence which can affect vibration of the diaphragm 121 is not generated.

Furthermore, in one specific embodiment of the present application, the first part 31, the second part 32 and the connection part 33 are integrally arranged, thereby not only ensuring that the thermally conductive member 3 has sufficient structural strength, but also ensuring smooth heat conduction in the thermally conductive member 3. In addition, the cross section area of the connecting part of the first part 31 and the connection part 32 along a thickness direction is greater than the cross section area of the connecting part of the connection part 33 and the first part 31 along the thickness direction. Therefore, the first part 31 and the sound channel 112 have a larger contact area, and heat exchange can be accelerated.

As shown in FIG. 4, the first part 31 comprises a metal heat radiation sheet 311 which is in integral injection molding with the first housing body 11, and a thermally conductive element 312 which is adhered to the outer surface of the metal heat radiation sheet 311. Preferably, the metal heat radiation sheet 311 is a steel piece or a copper piece, so that the heat exchange efficiency of the thermally conductive element 312 with the sound channel 112 can be improved.

What needs to be further explained is that in other preferable application modes of the present application, the thermally conductive member 3 is a liquid cooling type thermally conductive vessel. Due to adoption of the liquid cooling type thermally conductive vessel, a liquid in the second part 32 is evaporated into vapor by the heat generated by the heat source component 2, the vapor passes through the hollow connection part 33, is gradually cooled into a liquid in the first part 31, and further flows back to the second part 32 through a capillary core in the thermally conductive vessel. The process is continuously repeated, and thus the heat radiation of the heat source component 2 is remarkably improved.

When the sounding device 100 executes heat radiation operation, a pulse signal of a low frequency (lower than 1000 Hz) can be input, the diaphragm 121 of the speaker unit 12 is driven to vibrate, and the air in the front acoustic cavity 111 and the sound channel 112 is driven to flow to achieve an air cooling effect.

When the sounding device 100 does not execute a music play task, the pulse signal can be broadcast independently. When the music play task is executed, the pulse signal can be overlapped with a music signal. Since the signal is a pulse signal of an ultralow frequency, the signal is not heard by ears, and a normal hearing effect is not affected.

Definitely, in another specific application mode, the thermally conductive member 3 can be also a solid heat conduction metal piece, so that the heat radiation speed of the heat source component 2 can be increased by taking the advantage of good heat conduction performance of the metal piece.

In the specific application mode of the present application, the first housing body 11 comprises a lower housing body 114 and an upper housing body 115 which is assembled with the lower housing body 114 to form the first accommodation space 110. The upper housing body 115 comprises a top wall 1151 and a side wall 1152 which extends to the direction of the lower housing body 114 from the top wall 1151. The sound channel 112 is arranged on the upper housing body 115. The first part 31 is embedded into the top wall 1151.

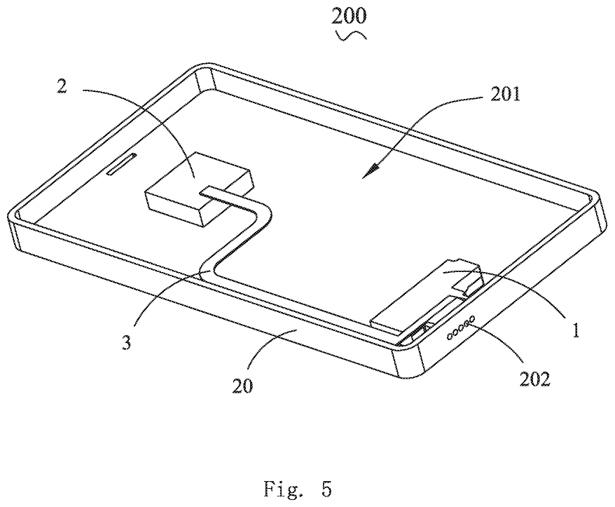

Referring to FIG. 5, the present application further provides a mobile terminal 200 which comprises the sounding device 100, a second housing 20 with a second accommodation space 201, and a voice outlet 202 arranged in the second housing 20; the sounding device 100 is accommodated in the second housing 20; the sound channel 112 communicates with the voice outlet 202, so as to conduct the heat of the heat source component 2 out of the mobile terminal 200.

Actually, the mobile terminal 200 further comprises other necessary components such as a circuit board, a battery and a CPU, all of the components are accommodated in the second housing 20, and heating elements in the components, such as the CPU and the battery are equivalent to the heat source component 2.

The present application has the beneficial effects that the thermally conductive member is in direct contact with the sound channel, and the heat radiation efficiency is high; by virtue of an air cooling effect of the speaker unit, the heat of the thermally conductive member is rapidly conduced into outer air, and thus the heat radiation efficiency can be remarkably improved; and due to adoption of a liquid cooling type thermally conductive vessel, an effect that liquid cooling and air cooling are combined is achieved, and the heat radiation efficiency can be further improved.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A sounding device, comprising:
a speaker box for generating sound, comprising a first housing body with a first accommodation space, and a speaker unit accommodated in the first housing body and comprising a diaphragm for generating sounding;
a heat source component spaced from the speaker box;
a thermally conductive member connected with the speaker box and the heat source component; wherein
the diaphragm partitions the first accommodation space into a front acoustic cavity between the diaphragm and the first housing body;
the first housing body comprises a sound channel communicating the front acoustic cavity with the outside and a through opening penetrating through the first housing body;
the thermally conductive member comprises a first part which is embedded into the first housing body and completely covers the through opening, a second part connected with the heat source component, and a connection part connected with the first part and the second part;
the first part and the first housing body encircles the sound channel together; the first part is arranged at one end of the sound channel close to the front acoustic cavity; and heat generated by the heat source component is conducted into the air in the sound channel through the thermally conductive member.

2. The sounding device as described in claim 1, wherein the first part comprises a metal heat radiation sheet in integral injection molding with the first housing body and the thermally conductive element adhered to an outer surface of the metal heat radiation sheet.

3. The sounding device as described in claim 2, wherein the metal heat radiation sheet is a steel piece or a copper piece.

4. The sounding device as described in claim 1, wherein the thermally conductive member is a liquid cooling type thermally conductive vessel.

5. The sounding device as described in claim 1, wherein the thermally conductive member is a solid heat conduction metal piece.

6. The sounding device as described in claim 1, wherein an inner surface of the first part right aligned to the sound channel is flush with an inner surface of the first housing body on a circumferential side.

7. The sounding device as described in claim 1, wherein the first part, the second part and the connection part are integrally arranged.

8. The sounding device as described in claim 6, wherein the first part, the second part and the connection part are integrally arranged.

9. The sounding device as described in claim 7, wherein a cross section area of the connecting part of the first part and the connection part along a thickness direction is greater than a cross section area of the connecting part of the connection part and the first part along the thickness direction.

10. The sounding device as described in claim 8, wherein the cross section area of the connecting part of the first part and the connection part along a thickness direction is greater than a cross section area of the connecting part of the connection part and the first part along the thickness direction.

11. The sounding device as described in claim 1, wherein the first housing body comprises a lower housing body and an upper housing body which is assembled with the lower housing body to form the first accommodation space; the upper housing body comprises a top wall and a side wall which extends to the lower housing body from the top wall; the sound channel is arranged at the upper housing body; and the first part is embedded into the top wall.

12. A mobile terminal, comprising a sounding device as described in claim 1, a second housing with a second accommodation space, and a voice outlet formed in the second housing, wherein the sounding device is accommodated in the second housing, and the sound channel communicates with the voice outlet.
